(19) United States
(12) Patent Application Publication
(10) Pub. No.: US 2024/0274615 A1
(43) Pub. Date: Aug. 15, 2024

(54) DISPLAY DEVICE

(71) Applicant: Samsung Display Co., LTD., Yongin-si (KR)

(72) Inventors: DONG-HOON LEE, Yongin-si (KR); HAEMIN KIM, Yongin-si (KR); YOUNGWAN SEO, Yongin-si (KR); GEUNHO LEE, Yongin-si (KR)

(21) Appl. No.: 18/368,494

(22) Filed: Sep. 14, 2023

(30) Foreign Application Priority Data
Feb. 14, 2023 (KR) 10-2023-0019354

(51) Int. Cl. H01L 27/12; H10K 59/131

(52) U.S. Cl. CPC H01L 27/124; H10K 59/131; H10K 77/111

(57) ABSTRACT

A display device includes: a substrate including a display area and a peripheral area adjacent to the display area; a power line in the peripheral area on the substrate; a plurality of power connection lines in the peripheral area on the substrate, extending in one direction, and connected to the power line; and a plurality of data lines in the peripheral area on the substrate, extending in the one direction, on a different layer from the power connection lines, and spaced apart from the power connection lines in a plan view.

### CROSS-REFERENCE TO RELATED APPLICATION(S)

The present application claims priority to and the benefit of Korean Patent Application No. 10-2023-0019354 filed on Feb. 14, 2023, in the Korean Intellectual Property Office (KIPO), the entire disclosure of which is incorporated herein by reference.

### BACKGROUND

### 1. Field

Aspects of some embodiments relate to a display device.

### 2. Description of the Related Art

As information technology develops, the importance of display devices, which provide a communication medium between users and information, is being highlighted. Accordingly, display devices such as liquid crystal display devices, organic light emitting display devices, plasma display devices, or the like are widely used in various fields.

A display device generally includes a display panel that displays images and a driver that controls the image displayed on the display panel. The display panel generally includes data lines, scan lines, and pixels. The driver includes a data driver that provides a data signal to the data lines, a scan driver that provides a scan signal to the scan lines and a controller that controls the data driver and the scan driver. The driver may include a demultiplexer that branches the data signal provided from the data driver.

The above information disclosed in this Background section is only for enhancement of understanding of the background and therefore the information discussed in this Background section does not necessarily constitute prior art.

### SUMMARY

Aspects of some embodiments relate to a display device. For example, aspects of some embodiments relate to a display device that provides visual information.

Aspects of some embodiments include a display device with relatively improved display quality.

A display device according to some embodiments of the present disclosure includes a substrate including a display area and a peripheral area adjacent to the display area, a power line in the peripheral area on the substrate, power connection lines in the peripheral area on the substrate, extending in one direction, and connected to the power line, and data lines in the peripheral area on the substrate, extending in the one direction, on a different layer from the power connection lines, and spaced apart from the power connection lines in a plan view.

According to some embodiments, the data lines may be between the power connection lines adjacent to each other in the plan view.

According to some embodiments, the power connection lines and the data lines may be alternately arranged in the plan view.

According to some embodiments, the display device may further include a via insulating layer on the data lines. According to some embodiments, the power connection lines may be on the via insulating layer.

According to some embodiments, the display device may further include a via insulating layer on the power connection lines. According to some embodiments, the data lines may be on the via insulating layer.

According to some embodiments, each of the power connection lines may include a first power connection line and a second power connection line, and the first power connection line and the second power connection line may be on different layers.

According to some embodiments, the display device may further include a first via insulating layer on the first power connection line and a second via insulating layer on the first via insulating layer. According to some embodiments, the data lines may be between the first via insulating layer and the second via insulating layer, and the second power connection line may be on the second via insulating layer.

According to some embodiments, the first power connection line and the second power connection line may entirely overlap in the plan view.

According to some embodiments, the data lines may include first data lines and second data lines, and a first data signal applied to the first data lines may be different from a second data signal applied to the second data lines.

According to some embodiments, each of the power connection lines may be between the first data line and the second data line adjacent to each other in the plan view.

According to some embodiments, a number of the power connection lines may be less than a number of the data lines.

A display device according to some embodiments of the present disclosure includes a substrate including a display area, a bending area adjacent to the display area, and a pad area adjacent to the bending area, demultiplexers in the pad area on the substrate, a power line in the pad area on the substrate, data connection lines in the pad area on the substrate, extending in one direction, and connected to the demultiplexers, power connection lines in the bending area on the substrate, extending in the one direction, and connected to the power line, and data lines in the bending area on the substrate, extending in the one direction, on a different layer from the power connection lines, connected to the data connection lines, and spaced apart from the power connection lines in a plan view.

According to some embodiments, the power connection lines and the data lines may be alternately arranged in the plan view.

According to some embodiments, the display device may further include a via insulating layer on the data lines. According to some embodiments, the power connection lines may be on the via insulating layer.

According to some embodiments, the display device may further include a via insulating layer on the power connection lines. According to some embodiments, the data lines may be on the via insulating layer.

According to some embodiments, each of the power connection lines may include a first power connection line and a second power connection line on different layers, and the first power connection line and the second power connection line may entirely overlap in the plan view.

According to some embodiments, the display device may further include a first via insulating layer on the first power connection line and a second via insulating layer on the first via insulating layer. According to some embodiments, the data lines may be between the first via insulating layer and the second via insulating layer, and the second power connection line may be on the second via insulating layer.

According to some embodiments, the data lines may include first data lines and second data lines, a first data signal applied to the first data lines may be different from a second data signal applied to the second data lines, and each of the power connection lines may be between the first data line and the second data line adjacent to each other in the plan view.

According to some embodiments, each of the data connection lines may include a first data connection line connected to the first data line and a second data connection line connected to the second data line, and one of the demultiplexers may be connected to the first data connection line and the second data connection line.

According to some embodiments, a number of the power connection lines may be less than a number of the data lines.

In a display device according to some embodiments of the present disclosure, the display device may include data lines and power connection lines connected to power lines. Because each of the power connection lines is between the data lines adjacent to each other in a plan view, a coupling phenomenon that occurs between the data lines adjacent to each other may be relatively reduced. In addition, because the data lines and the power connection lines are on different layers, a sufficient space for the data lines may be secured. Accordingly, display quality of the display device may be relatively improved.

In addition, because the display device further includes demultiplexers connected to the data lines and located in a pad area on one side of a display area, dead space of the display device may be relatively reduced.

### BRIEF DESCRIPTION OF THE DRAWINGS

FIG. 1 is a plan view illustrating a display device according to some embodiments of the present disclosure.

FIG. 2 is a cross-sectional view taken along the line I-I′ of FIG. 1.

FIG. 3 is an enlarged plan view of the area A of FIG. 1.

FIG. 4 is an enlarged plan view of the area B of FIG. 3.

FIG. 5 is a cross-sectional view taken along the line II-II′ of FIG. 3.

FIG. 6 is a cross-sectional view taken along the line III-III′ of FIG. 3.

FIG. 7 is a cross-sectional view illustrating another example of FIG. 5.

FIG. 8 is a cross-sectional view illustrating still another example of FIG. 5.

FIG. 9 is a plan view illustrating another example of FIG. 3.

FIG. 10 is a plan view illustrating still another example of FIG. 3.

### DETAILED DESCRIPTION

Hereinafter, aspects of some embodiments of the present disclosure will be described in more detail with reference to the accompanying drawings. The same reference numerals are used for the same components in the drawings, and redundant descriptions of the same components will be omitted.

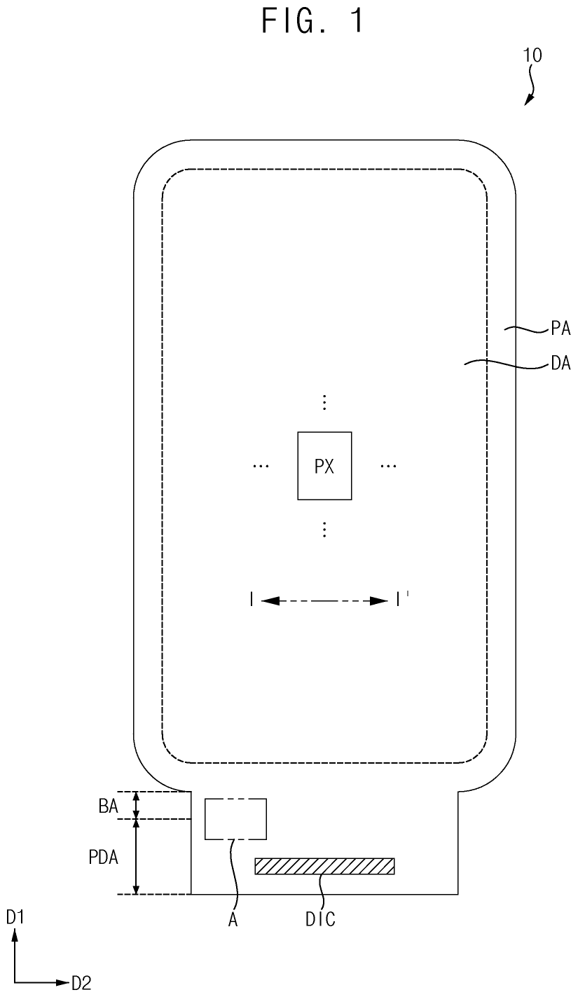

FIG. 1 is a plan view illustrating a display device according to some embodiments of the present disclosure.

Referring to FIG. 1, a display device 10 according to some embodiments of the present disclosure may include a display area DA and a peripheral area PA adjacent to the display area DA.

The display area DA may be an area that displays images by generating light. A plurality of pixels PX that display images may be located in the display area DA. The pixels PX may be arranged in a matrix form along a first direction D1 and a second direction D2 intersecting the first direction D1. For example, the second direction D2 may be perpendicular to the first direction D1. Each of the pixels PX may include a light emitting element and a pixel circuit that drives the light emitting element. According to some embodiments, the light emitting element may include an organic light emitting diode, and the pixel circuit may include at least one thin film transistor.

Lines that provide signals or power to each of the pixels PX may be located in the display area DA. For example, a data line, a scan line, a power line, or the like may be located in the display area DA. A data signal, a scan signal, a power voltage, or the like may be applied to each of the pixels PX through the lines.

The peripheral area PA may be an area that does not display an image. The peripheral area PA may surround at least a portion of the display area DA. For example, the peripheral area PA may entirely surround the display area DA.

The peripheral area PA may include a bending area BA and a pad area PDA. The bending area BA may be adjacent to the pad area PDA in the first direction D1, and the display area DA may be adjacent to the bending area BA in the first direction D1. For example, the bending area BA may be located between the display area DA and the pad area PDA.

The bending area BA may be an area in which the display device 10 is bendable. The display device 10 may be bent at the bending area BA, so that at least a portion of the pad area PDA may overlap the display area DA. For example, the display device 10 may be bent so that the pad area PDA is located on a rear surface of the display area DA.

A driver DIC that drives the pixels PX, an inspection circuit that inspects the display device 10, or the like may be located in the pad area PDA.

The driver DIC may generate the data signal. The driver DIC may generate the data signal, and may supply the data signal to the data line. Accordingly, the data line may apply the data signal to the pixels PX. According to some embodiments, the driver DIC may be implemented with one or more integrated circuits (ICs).

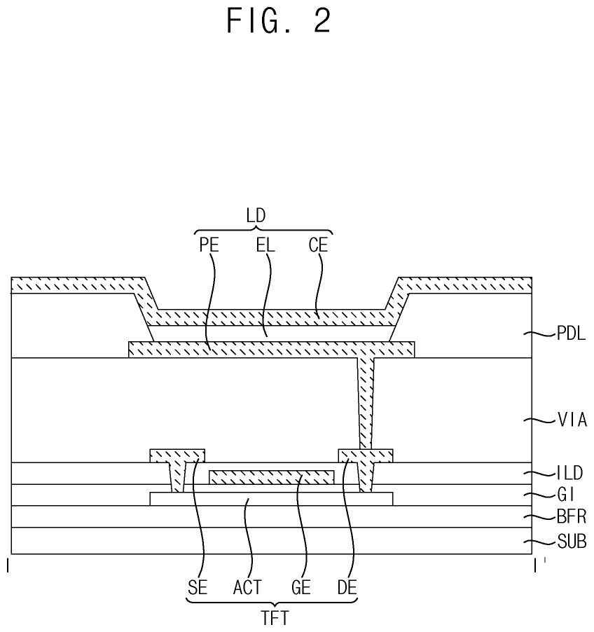

FIG. 2 is a cross-sectional view taken along the line I-I′ of FIG. 1. For example, FIG. 2 may be a cross-sectional view of the display area DA included in the display device 10.

Referring to FIGS. 1 and 2, the display device 10 may include a substrate SUB, a buffer layer BFR, an active pattern ACT, a gate insulating layer GI, a gate electrode GE, an interlayer insulating layer ILD, a source electrode SE, a drain electrode DE, a via insulating layer VIA, a pixel electrode PE, a pixel defining layer PDL, an light emitting layer EL and a common electrode CE.

The substrate SUB may include a transparent or opaque material. Examples of materials that may be used as the substrate SUB may include plastic, glass, quartz, or the like. These may be used alone or in combination with each other.

The buffer layer BFR may be located on the substrate SUB. The buffer layer BFR may prevent or reduce diffusion of impurities such as contaminants, oxygen, and/or moisture to an upper portion of the substrate SUB through the substrate SUB. The buffer layer BFR may include an inorganic insulating material. Examples of inorganic insulating materials that may be used as the buffer layer BFR may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These may be used alone or in combination with each other.

The active pattern ACT may be located on the buffer layer BFR. The active pattern ACT may include a source area, a drain area and a channel area located between the source area and the drain area. The active pattern ACT may include a silicon semiconductor material or an oxide semiconductor material. Examples of silicon semiconductor materials that may be used as the active pattern ACT may include amorphous silicon, polycrystalline silicon, or the like. Examples of oxide semiconductor materials that may be used as the active pattern ACT may include indium gallium zinc oxide (IGZO), indium tin zinc oxide (ITZO), or the like. These may be used alone or in combination with each other.

The gate insulating layer GI may be located on the active pattern ACT. The gate insulating layer GI may cover the active pattern ACT. The gate insulating layer GI may include an inorganic insulating material. Examples of inorganic insulating materials that may be used as the gate insulating layer GI may include silicon oxide, silicon nitride, silicon oxynitride, or the like. These may be used alone or in combination with each other.

The gate electrode GE may be located on the gate insulating layer GI. The gate electrode GE may overlap the channel area of the active pattern ACT. The gate electrode GE may include a conductive material. Examples of conductive materials that may be used as the gate electrode GE may include aluminum (Al), platinum (Pt), palladium (Pd), silver (Ag), magnesium (Mg), gold (Au), nickel (Ni), neodium (Nd), iridium (Ir), chromium (Cr), lithium (Li), calcium (Ca), molybdenum (Mo), titanium (Ti), tungsten (W), copper (Cu), or the like. These may be used alone or in combination with each other.

The interlayer insulating layer ILD may be located on the gate electrode GE. The interlayer insulating layer ILD may cover the gate electrode GE. The interlayer insulating layer ILD may include an inorganic insulating material. Examples of inorganic insulating materials that may be used as the interlayer insulating layer ILD may include silicon oxide, silicon nitride, silicon oxynitride, or the like. These may be used alone or in combination with each other.

The source electrode SE and the drain electrode DE may be located on the interlayer insulating layer ILD. The source electrode SE may contact the source area of the active pattern ACT through a contact hole penetrating portions of the interlayer insulating layer ILD and the gate insulating layer GI. The drain electrode DE may contact the drain area of the active pattern ACT through a contact hole penetrating portions of the interlayer insulating layer ILD and the gate insulating layer GI. Each of the source electrode SE and the drain electrode DE may include a conductive material. Examples of the conductive material that may be used as each of the source electrode SE and the drain electrode DE may include aluminum, platinum, palladium, silver, magnesium, gold, nickel, neodymium, iridium, chromium, lithium, calcium, molybdenum, titanium, tungsten, copper, or the like. These may be used alone or in combination with each other.

Accordingly, a thin film transistor TFT including the active pattern ACT, the gate electrode GE, the source electrode SE and the drain electrode DE may be located in the display area DA on the substrate SUB.

The via insulating layer VIA may be located on the source electrode SE and the drain electrode DE. The via insulating layer VIA may cover the source electrode SE and the drain electrode DE. The via insulating layer VIA may have a single layer or multiple layers. The via insulating layer VIA may include an organic insulating material. Examples of insulating materials that may be used as the via insulating layer VIA may include photoresist, polyacrylic resin, polyimide resin, acrylic resin, or the like. These may be used alone or in combination with each other.

The pixel electrode PE may be located on the via insulating layer VIA. The pixel electrode PE may contact the drain electrode DE through a contact hole penetrating a portion of the via insulating layer VIA. That is, the pixel electrode PE may be electrically connected to the thin film transistor TFT. The pixel electrode PE may include a conductive material. Examples of conductive materials that may be used as the pixel electrode PE may include aluminum, platinum, palladium, silver, magnesium, gold, nickel, neodymium, iridium, chromium, lithium, calcium, molybdenum, titanium, tungsten, copper, indium tin oxide, indium zinc oxide, or the like. These may be used alone or in combination with each other.

The pixel defining layer PDL may be located on the via insulating layer VIA. An opening exposing at least a portion of an upper surface of the pixel electrode PE may be defined in the pixel defining layer PDL. The pixel defining layer PDL may include an organic insulating material. Examples of organic insulating materials that may be used as the pixel defining layer PDL may include photoresist, polyacrylic resin, polyimide resin, acrylic resin, or the like. These may be used alone or in combination with each other.

The light emitting layer EL may be located on the pixel electrode PE. Specifically, the light emitting layer EL may be located on the pixel electrode PE exposed by the opening of the pixel defining layer PDL. The light emitting layer EL may include an organic material, and may emit light (e.g., of a set or predetermined color).

The common electrode CE may be located on the light emitting layer EL and the pixel defining layer PDL. The common electrode CE may include a conductive material. Examples of conductive materials that may be used as the common electrode CE may include aluminum, platinum, silver, magnesium, gold, chromium, tungsten, titanium, or the like. These may be used alone or in combination with each other.

Accordingly, a light emitting element LD including the pixel electrode PE, the light emitting layer EL and the common electrode CE may be located in the display area DA on the substrate SUB. The light emitting element LD may emit light based on a driving current transmitted from the thin film transistor TFT.

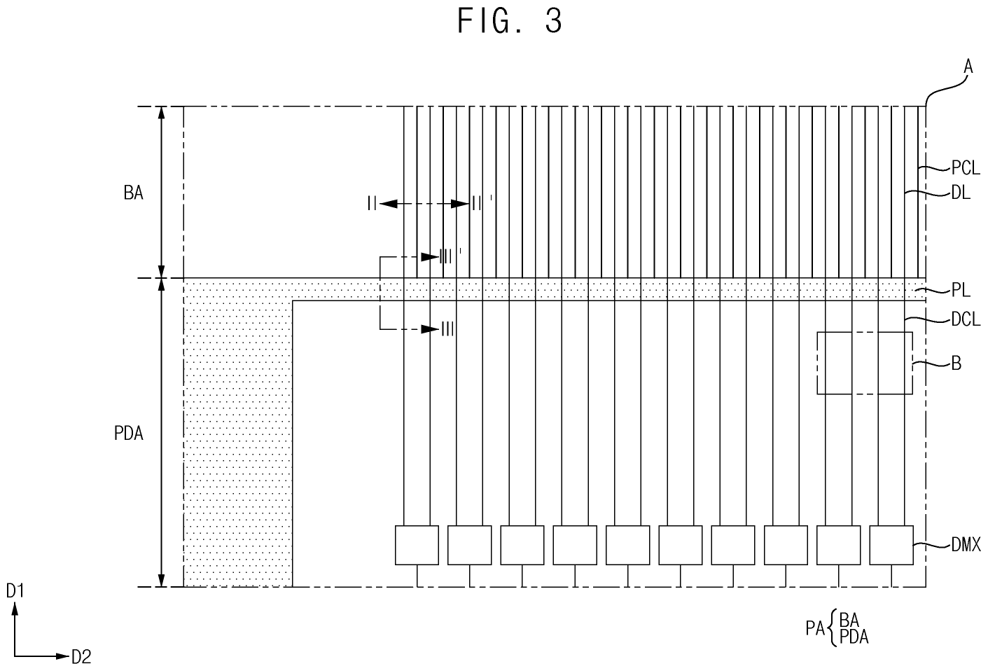

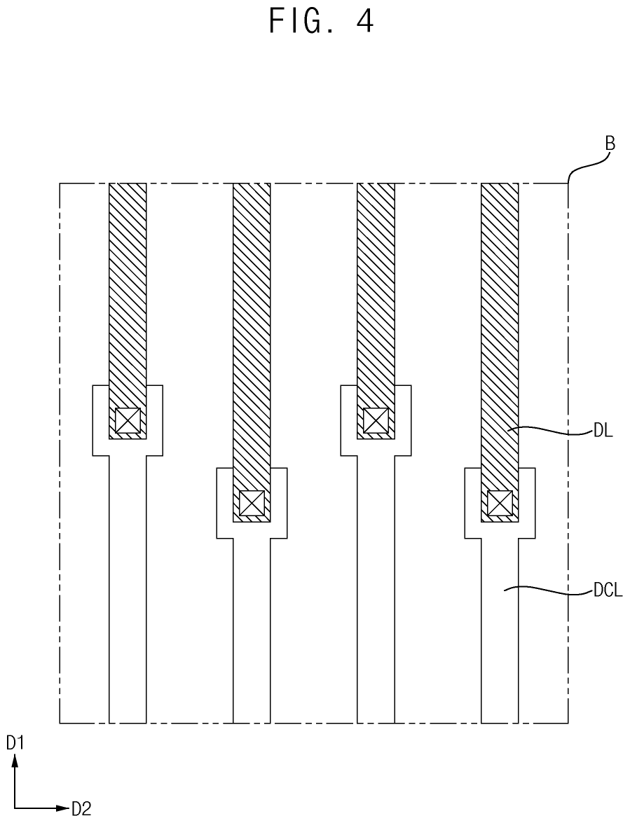

FIG. 3 is an enlarged plan view of area A of FIG. 1. FIG. 4 is an enlarged plan view of area B of FIG. 3. For example, FIG. 3 may be an enlarged plan view of the bending area BA and the pad area PDA included in the display device 10. FIG. 4 may be an enlarged plan view of data connection lines DCL and data lines DL in the pad area PDA.

Referring to FIGS. 1, 3 and 4, the display device 10 may include a power line PL, a plurality of power connection lines PCL, a plurality of demultiplexers DMX, a plurality of data connection lines DCL and a plurality of data lines DL.

The power line PL may be located in the pad area PDA. For example, the power line PL may extend in the first direction D1 and the second direction D2 in the pad area PDA. The power line PL may supply the power voltage to the power connection lines PCL.

The power connection lines PCL may be located in the bending area BA.

Each of the power connection lines PCL may extend in the first direction D1. Each of the power connection lines PCL may be connected to the power line PL. For example, each of the power connection lines PCL may be connected to a portion of the power line PL extending in the second direction D2.

Each of the power connection lines PCL may extend to the display area DA. Each of the power connection lines PCL may be connected to the pixels PX located in the display area DA. According to some embodiments, each of the power connection lines PCL may apply the power voltage to the pixels PX. For example, the power voltage may be ELVSS or ELVDD.

The demultiplexers DMX may be located in the pad area PDA. The demultiplexers DMX may be arranged along the second direction D2. Each of the demultiplexers DMX may receive the data signal from the driver DIC. Each of the demultiplexers DMX may demux the data signal, and may supply the data signal to the data connection lines DCL.

The data connection lines DCL may be located in the pad area PDA. Each of the data connection lines DCL may extend in the first direction D1. The data connection lines DCL may be respectively connected to the demultiplexers DMX.

According to some embodiments, each of the demultiplexers DMX may be connected to two data connection lines DCL. Each of the demultiplexers DMX may supply different data signals to the two data connection lines DCL. For example, one of the two data connection lines DCL may receive a first data signal, and the other one of the two data connection lines DCL may receive a second data signal different from the first data signal. According to some embodiments, the first data signal may be red and blue data signals, and the second data signal may be a green data signal. However, the present disclosure is not limited thereto. Alternatively, the first data signal may be a green data signal, and the second data signal may be red and blue data signals. According to some embodiments, each of the demultiplexers DMX may be connected to four or more even-numbered data connection lines DCL.

A portion of each of the data lines DL may be located in the bending area BA. In addition, another portion of each of the data lines DL may be located in the pad area PDA. In other words, each of the data lines DL may extend from the bending area BA to the pad area PDA. Each of the data lines DL may extend in the first direction D1.

The data lines DL may be respectively connected to the data connection lines DCL. The data lines DL may be respectively connected to the data connection lines DCL through contact holes. Accordingly, the data lines DL may receive the data signal through the data connection lines DCL.

Each of the data lines DL may extend to the display area DA. Each of the data lines DL may be connected to the pixels PX located in the display area DA. According to some embodiments, each of the data lines DL may apply the data signal to the pixels PX.

According to some embodiments, the data lines DL may be spaced apart from the power connection lines PCL in a plan view. That is, the data lines DL may not overlap the power connection lines PCL in the plan view. In other words, each of the data lines DL may be located between the power connection lines PCL adjacent to each other in the plan view. For example, the power connection lines PCL and the data lines DL may be alternately arranged in the plan view.

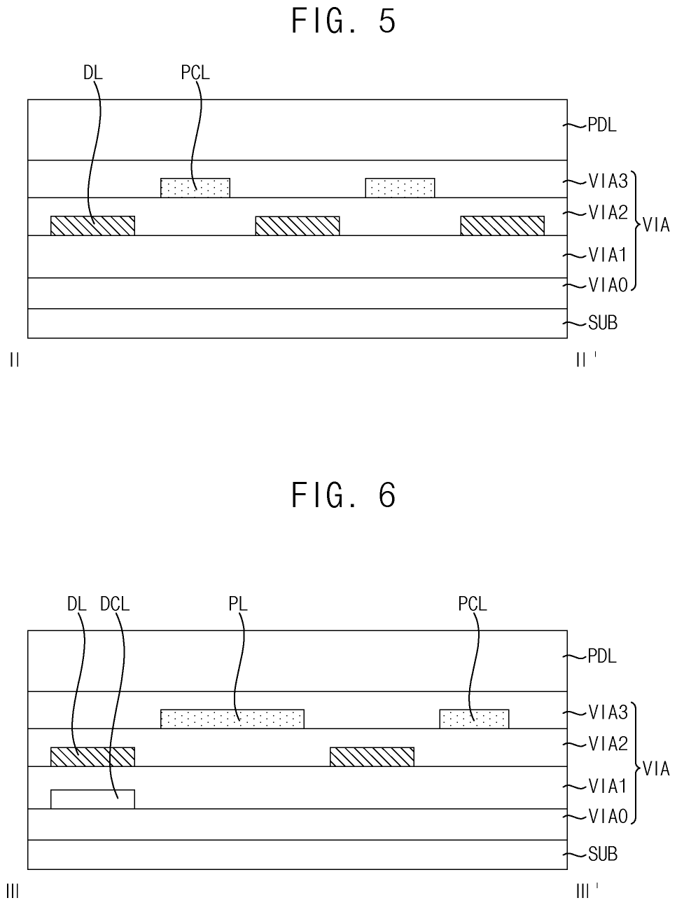

FIG. 5 is a cross-sectional view taken along line II-II′ of FIG. 3. FIG. 6 is a cross-sectional view taken along the line III-III′ of FIG. 3. For example, FIG. 5 may be a cross-sectional view of the bending area BA included in the display device 10. FIG. 6 may be a cross-sectional view of the pad area PDA and the bending area BA included in the display device 10.

Hereinafter, descriptions overlapping those of the display device 10 described with reference to FIG. 2 will be omitted or simplified.

Referring to FIGS. 2, 3, 5 and 6, the display device 10 may include the substrate SUB, the data connection lines DCL, the data lines DL, the power line PL, the power connection lines PCL, the via insulating layer VIA and the pixel defining layer PDL in the bending area BA and the pad area PDA.

The via insulating layer VIA and the pixel defining layer PDL may be sequentially arranged on the substrate SUB. The substrate SUB may contact the via insulating layer VIA in the bending area BA.

The via insulating layer VIA may include multiple layers. For example, in the bending area BA and the pad area PDA, the via insulating layer VIA may include a zeroth via insulating layer VIA0, a first via insulating layer VIA1, a second via insulating layer VIA2 and a third via insulating layer VIA3. The zeroth via insulating layer VIA0 may be located on the substrate SUB, and the first via insulating layer VIA1 may be located on the zeroth via insulating layer VIA0. The second via insulating layer VIA2 may be located on the first via insulating layer VIA1, and the third via insulating layer VIA3 may be located on the second via insulating layer VIA2.

The data lines DL and the power connection lines PCL may be located on different layers in the bending area BA. According to some embodiments, the data lines DL may be located on the first via insulating layer VIA1. The second via insulating layer VIA2 may be located on the data lines DL, and may cover the data lines DL. The power connection lines PCL may be located on the second via insulating layer VIA2. The third via insulating layer VIA3 may be located on the power connection lines PCL, and may cover the power connection lines PCL.

The power connection lines PCL may not overlap the data lines DL. That is, the power connection lines PCL may be located between the data lines DL adjacent to each other in the plan view.

According to some embodiments, the power line PL and the power connection lines PCL may be located on the same layer. That is, the power line PL and the power connection lines PCL may be formed using the same material and through the same process. For example, the power line PL may be located on the second via insulating layer VIA2, and the third via insulating layer VIA3 may cover the power line PL. However, the present disclosure is not limited thereto. Alternatively, the power line PL and the power connection lines PCL may be located on different layers.

According to some embodiments, the data connection lines DCL and the data lines DL may be located on different layers. For example, the data lines DL may be located on the data connection lines DCL. The data connection lines DCL may be located on the zeroth via insulating layer VIA0, and the first via insulating layer VIA1 may cover the data connection lines DCL.

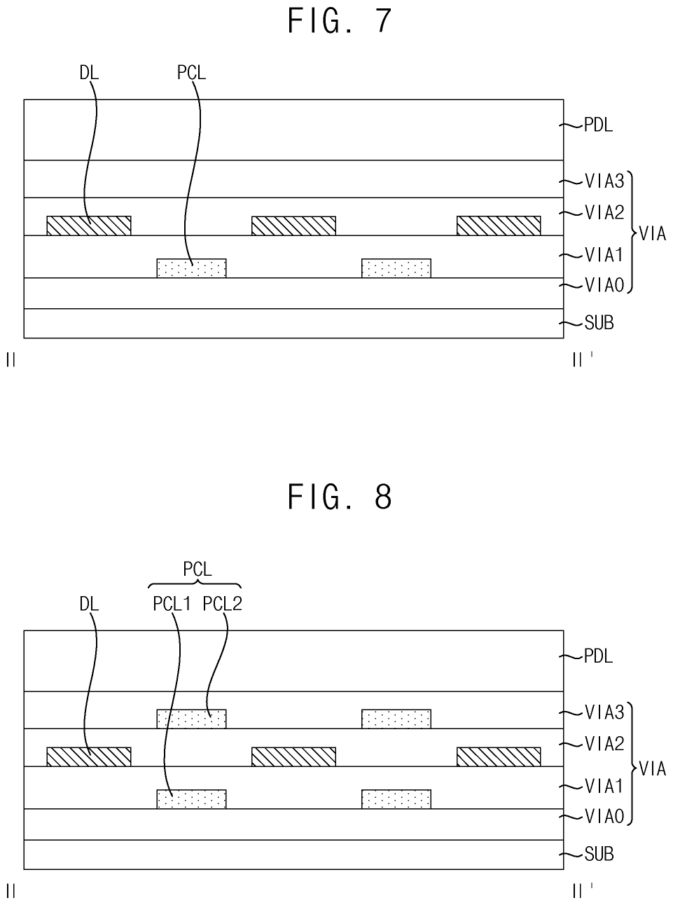

FIG. 7 is a cross-sectional view illustrating another example of FIG. 5. Hereinafter, descriptions overlapping those of the display device 10 described with reference to FIG. 5 will be omitted or simplified.

Referring to FIG. 7, the data lines DL and the power connection lines PCL may be located on different layers in the bending area BA.

According to some embodiments, the power connection lines PCL may be located on the zeroth via insulating layer VIA0. The first via insulating layer VIA1 may be located on the power connection lines PCL, and may cover the power connection lines PCL. The data lines DL may be located on the first via insulating layer VIA1. The second via insulating layer VIA2 may be located on the data lines DL, and may cover the data lines DL.

FIG. 8 is a cross-sectional view illustrating still another example of FIG. 5. Hereinafter, descriptions overlapping those of the display device 10 described with reference to FIG. 5 will be omitted or simplified.

Referring to FIG. 8, each of the power connection lines PCL may include a first power connection line PCL1 and a second power connection line PCL2. The data lines DL, the first power connection line PCL1 and the second power connection line PCL2 may be located on different layers in the bending area BA.

According to some embodiments, the first power connection line PCL1 may be located on the zeroth via insulating layer VIA0. The first via insulating layer VIA1 may be located on the first power connection line PCL1, and may cover the first power connection line PCL1. The data lines DL may be located on the first via insulating layer VIA1. The second via insulating layer VIA2 may be located on the data lines DL, and may cover the data lines DL. The second power connection line PCL2 may be located on the second via insulating layer VIA2. The third via insulating layer VIA3 may be located on the second power connection line PCL2, and may cover the second power connection line PCL2.

According to some embodiments, the first power connection line PCL1 and the second power connection line PCL2 may entirely overlap in the plan view. In addition, each of the first power connection line PCL1 and the second power connection line PCL2 may not overlap the data lines DL in the plan view.

The display device 10 according to some embodiments of the present disclosure may include the power connection lines PCL connected to the data lines DL and the power line PL. Each of the power connection lines PCL may be located between the data lines DL adjacent to each other in the plan view, thereby reducing a coupling phenomenon between the data lines DL adjacent to each other. In addition, because the data lines DL and the power connection lines PCL may be located on different layers, a space for the data lines DL may be secured. Accordingly, display quality of the display device 10 may be improved.

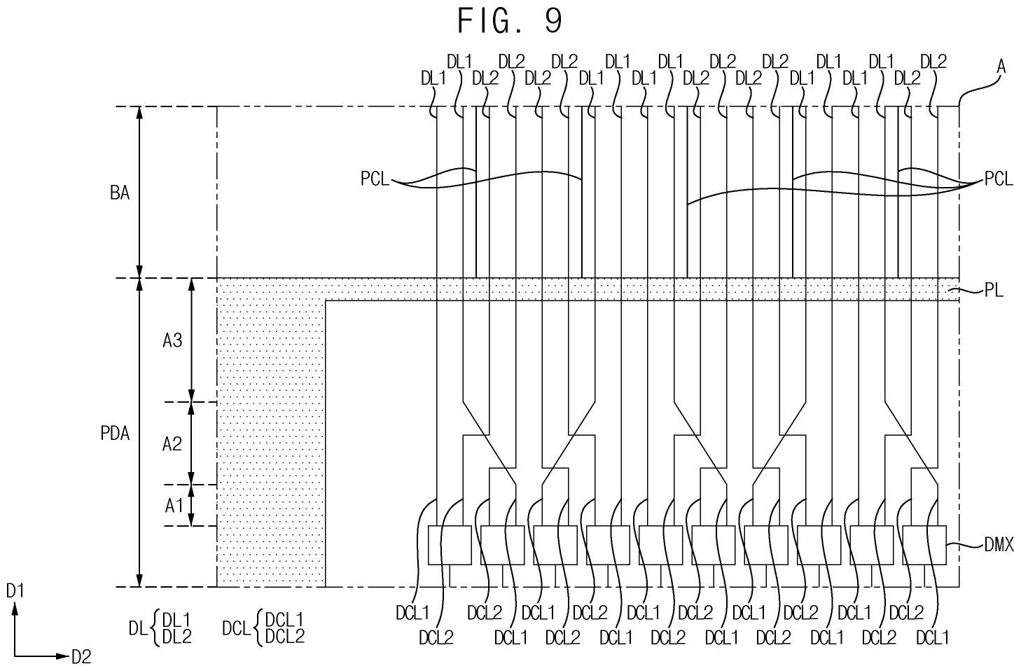

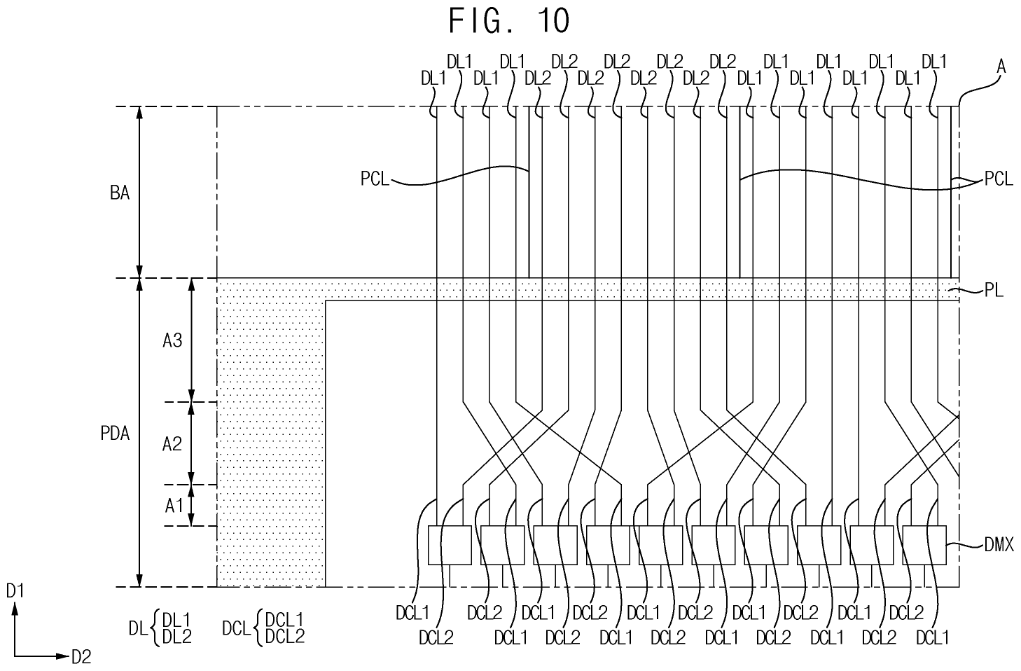

FIG. 9 is a plan view illustrating another example of FIG. 3. Hereinafter, descriptions overlapping those of the display device 10 described with reference to FIGS. 3, 4, 5, 6, 7 and 8 will be omitted or simplified.

Referring to FIGS. 1 and 9, the display device 10 may include the power line PL, the power connection lines PCL, the demultiplexers DMX, the data connection lines DCL and the data lines DL.

Each of the data connection lines DCL may include a first data connection line DCL1 and a second data connection line DCL2. Each of the data lines DL may include a first data line DL1 and a second data line DL2.

The pad area PDA may include a first area A1, a second area A2 and a third area A3. The second area A2 may be adjacent to the first area A1 in the first direction D1, and the third area A3 may be adjacent to the second area A2 in the first direction D1. For example, the first area A1 may be an area before the data connection lines DCL are mixed, the second area A2 may be an area where the data connection lines DCL are mixed, and the third area A3 may be an area after the data connection lines DCL are mixed.

Each of the demultiplexers DMX may be connected to the first data connection line DCL1 and the second data connection line DCL2. In addition, the first data connection line DCL1 may be connected to the first data line DL1, and the second data connection line DCL2 may be connected to the second data line DL2. That is, each of the demultiplexers DMX may be electrically connected to the first data line DL1 and the second data line DL2.

Each of the demultiplexers DMX may supply different data signals to the first data connection line DCL1 and the second data connection line DCL2. For example, the first data connection line DCL1 and the first data line DL1 may receive the first data signal, and the second data connection line DCL2 and the second data line DL2 may receive the second data signal.

In the first area A1, the first data connection line DCL1 and the second data connection line DCL2 may be repeatedly arranged at regular intervals along the second direction D2. For example, in the first area A1, the first data connection lines DCL1 may be located in a (4n−3)-th column and a (4n)-th column, and the second data connection lines DCL2 may be located in a (4n−2)-th column and a (4n−1)-th column (where n is a natural number). That is, in the first area A1, one first data connection line DCL1, two second data connection lines DCL2, and one first data connection line DCL1 may be repeatedly arranged along the second direction D2.

The data connection lines DCL may be mixed in the second area A2. That is, some of the data connection lines DCL may cross each other. For example, some of the first data connection lines DCL1 may cross some of the second data connection lines DCL2. Accordingly, an arrangement of the data connection lines DCL in the third area A3 may be different from an arrangement of the data connection lines DCL in the first area A1.

By mixing the data connection lines DCL, in the third area A3, the first data connection lines DCL1 and the second data connection lines DCL2 may be repeatedly arranged at regular intervals along the second direction D2. For example, in the third area A3, the first data connection lines DCL1 may be located in a (8n−7)-th column, a (8n−6)-th column, a (8n−1)-th column and a (8n)-th column, and the second data connection lines DCL2 may be located in a (8n−5)-th column, a (8n−4)-th column, a (8n-3)-th column and a (8n−2)-th column (where n is a natural number). That is, in the third area A3, two first data connection lines DCL1, four second data connection lines DCL2, and two first data connection lines DCL1 may be repeatedly arranged along the second direction D2.

In the third area A3, each of the data connection lines DCL may be connected to the data line DL. Accordingly, the arrangement of the data connection lines DCL in the third area A3 may be the same as an arrangement of the data lines DL in the bending area BA. In other words, in the bending area BA, two first data lines DL1, four second data lines DL2, and two first data lines DL1 may be repeatedly arranged along the direction D2. That is, in the bending area BA, the data lines DL may have a 4 bundle structure.

In this case, because the first data lines DL1 may be repeatedly arranged by four and the second data lines DL2 may be repeatedly arranged by four, a coupling phenomenon between the first data signal and the second data signal may be relatively reduced.

The power connection lines PCL may be spaced apart from the data lines DL in the plan view. That is, the power connection lines PCL may not overlap the data lines DL in the plan view. According to some embodiments, each of the power connection lines PCL may be located between the first data line DL1 and the second data line DL2 adjacent to each other in the plan view. That is, each of the power connection lines PCL may be located between four first data lines DL1 and four second data lines DL2 in the plan view. In other words, four first data lines DL1 or four second data lines DL2 may be located between the power connection lines PCL adjacent to each other. Accordingly, the number of the power connection lines PCL may be less than the number of the data lines DL.

FIG. 10 is a plan view illustrating still another example of FIG. 3. Hereinafter, descriptions overlapping those of the display device 10 described with reference to FIG. 9 will be omitted or simplified.

Referring to FIGS. 1 and 10, the display device 10 may include the power line PL, the power connection lines PCL, the demultiplexers DMX, the data connection lines DCL and the data lines DL.

The pad area PDA may include the first area A1, the second area A2 and the third area A3.

In the first area A1, one first data connection line DCL1, two second data connection lines DCL2, and one first data connection line DCL1 may be repeatedly arranged along the second direction D2.

The data connection lines DCL may be mixed in the second area A2.

By mixing the data connection lines DCL, in the third area A3, the first data connection lines DCL1 and the second data connection lines DCL2 may be repeatedly arranged at regular intervals along the second direction D2. For example, in the third area A3, the first data connection lines DCL1 may be located in a (16n−15)-th column, a (16n−14)-th column, a (16n−13)-th column, a (16n−12)-th column, a (16n−3)-th column, a (16n−2)-th column, a (16n−1)-th column and a (16n)-th column, and the second data connection lines DCL2 may be located in a (16n−11)-th column, a (16n−10)-th column, a (16n−9)-th column, a (16n−8)-th column, a (16n−7)-th column, a (16n−6)-th column, a (16n−5)-th column and a (16n−4)-th column (where n is a natural number). That is, in the third area A3, four first data connection lines DCL1, eight second data connection lines DCL2, and four first data connection lines DCL1 may be repeatedly arranged along the second direction D2.

In the third area A3, each of the data connection lines DCL may be connected to the data line DL. An arrangement of the data connection lines DCL in the third area A3 may be the same as an arrangement of the data lines DL in the bending area BA. In other words, in the bending area BA, four first data lines DL1, eight second data lines DL2, and four first data lines DL1 may be repeatedly arranged along the direction D2. That is, the data lines DL in the bending area BA may have an 8-bundle structure.

In this case, because the first data lines DL1 may be repeatedly arranged by eight and the second data lines DL2 may be repeatedly arranged by eight, a coupling phenomenon between the first data signal and the second data signal may be relatively reduced.

The power connection lines PCL may not overlap the data lines DL in the plan view. According to some embodiments, each of the power connection lines PCL may be located between the first data line DL1 and the second data line DL2 adjacent to each other in the plan view. That is, each of the power connection lines PCL may be located between eight first data lines DL1 and eight second data lines DL2 in the plan view. In other words, eight first data lines DL1 or eight second data lines DL2 may be located between the power connection lines PCL adjacent to each other. Accordingly, the number of the power connection lines PCL may be less than the number of the data lines DL.

The display device 10 according to some embodiments of the present disclosure may include the first and second data connection lines DCL1 and DCL2 to be mixed and the first and second data lines DL1 and DL2 having the 4-bundle or 8-bundle structure. Each of the power connection lines PCL may be located between the first data line DL1 and the second data line DL2 adjacent to each other in the plan view, thereby reducing a coupling phenomenon that occurs between the first data line DL1 and the second data line DL2 adjacent to each other. Accordingly, display quality of the display device 10 may be improved.

Embodiments according to the present disclosure can be applied to various display devices. For example, embodiments according to the present disclosure are applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although aspects of some embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a display area and a peripheral area adjacent to the display area;
a power line in the peripheral area on the substrate;
a plurality of power connection lines in the peripheral area on the substrate, extending in one direction, and connected to the power line; and
a plurality of data lines in the peripheral area on the substrate, extending in the one direction, on a different layer from the power connection lines, and spaced apart from the power connection lines in a plan view.

2. The display device of claim 1, wherein the data lines are between the power connection lines adjacent to each other in the plan view.

3. The display device of claim 2, wherein the power connection lines and the data lines are alternately arranged in the plan view.

4. The display device of claim 1, further comprising:
a via insulating layer on the data lines,
wherein the power connection lines are on the via insulating layer.

5. The display device of claim 1, further comprising:
a via insulating layer on the power connection lines,
wherein the data lines are on the via insulating layer.

6. The display device of claim 1, wherein each of the power connection lines includes a first power connection line and a second power connection line, and
the first power connection line and the second power connection line are on different layers.

7. The display device of claim 6, further comprising:
a first via insulating layer on the first power connection line; and
a second via insulating layer on the first via insulating layer,
wherein the data lines are between the first via insulating layer and the second via insulating layer, and
the second power connection line is on the second via insulating layer.

8. The display device of claim 6, wherein the first power connection line and the second power connection line entirely overlap in the plan view.

9. The display device of claim 1, wherein the data lines include first data lines and second data lines, and
a first data signal applied to the first data lines is different from a second data signal applied to the second data lines.

10. The display device of claim 9, wherein each of the power connection lines is between a first data line and a second data line adjacent to each other in the plan view.

11. The display device of claim 10, wherein a number of the power connection lines is less than a number of the data lines.

12. A display device comprising:
a substrate including a display area, a bending area adjacent to the display area, and a pad area adjacent to the bending area;
a plurality of demultiplexers in the pad area on the substrate;
a power line in the pad area on the substrate;
a plurality of data connection lines in the pad area on the substrate, extending in one direction, and connected to the demultiplexers;
a plurality of power connection lines in the bending area on the substrate, extending in the one direction, and connected to the power line; and
a plurality of data lines in the bending area on the substrate, extending in the one direction, on a different layer from the power connection lines, connected to the data connection lines, and spaced apart from the power connection lines in a plan view.

13. The display device of claim 12, wherein the power connection lines and the data lines are alternately arranged in the plan view.

14. The display device of claim 12, further comprising:
a via insulating layer on the data lines,
wherein the power connection lines are on the via insulating layer.

15. The display device of claim 12, further comprising:
a via insulating layer on the power connection lines,
wherein the data lines are on the via insulating layer.

16. The display device of claim 12, wherein each of the power connection lines include a first power connection line and a second power connection line on different layers, and
the first power connection line and the second power connection line entirely overlap in the plan view.

17. The display device of claim 16, further comprising:
a first via insulating layer on the first power connection line; and
a second via insulating layer on the first via insulating layer,
wherein the data lines are between the first via insulating layer and the second via insulating layer, and
the second power connection line is on the second via insulating layer.

18. The display device of claim 12, wherein the data lines include first data lines and second data lines,
a first data signal applied to the first data lines is different from a second data signal applied to the second data lines, and
each of the power connection lines is between the first data line and the second data line adjacent to each other in the plan view.

19. The display device of claim 18, wherein each of the data connection lines includes a first data connection line connected to a first data line and a second data connection line connected to a second data line, and
one of the demultiplexers is connected to the first data connection line and the second data connection line.

20. The display device of claim 18, wherein a number of the power connection lines is less than a number of the data lines.
